(19) United States
(12) Patent Application Publication
(10) Pub. No.: US 2008/0278354 A1
(43) Pub. Date: Nov. 13, 2008

(54) System and Apparatus for Dynamically Assigning Functions for Keys of a Computerized Keyboard Based on the Analysis of Keystrokes

(76) Inventor: Peter Garrett, Aptos, CA (US)

Correspondence Address: CENTRAL COAST PATENT AGENCY, INC, 3 HANGAR WAY SUITE D, WATSONVILLE, CA, 95076, US

(21) Appl. No.: 12/118,093

(22) Filed: May 9, 2008

Related U.S. Application Data
(60) Provisional application No. 60/917,464, filed on May 11, 2007.

(51) Int. Cl. H03M 11/00

(52) U.S. Cl. 341/32

(57) ABSTRACT

A computer data entry includes a key frame including at least a top plate and a bottom plate, a key motion mechanism for enabling a range of vertical movement of the key, a permanent magnet producing a magnetic field affixed to the key frame, and an electromagnet affixed to the key motion mechanism. The permanent magnetic field repels the electromagnetic field when current is introduced into the electromagnet such that upon key depression, a disturbance in the electromagnetic field occurs as a result of like polarity of the magnetic fields, the disturbance analyzed to dynamically select a specific input function for the key.

### CROSS-REFERENCE TO RELATED APPLICATIONS

The present invention claims priority to a U.S. provisional patent application Ser. No. 60/917,464 entitled Magnetically Enhanced Computer Key filed on May 11, 2007 disclosure of which is incorporated in its entirety at least be reference.

### BACKGROUND OF THE INVENTION

1. Field of the Invention

The present invention is in the field of computer input devices, more particularly, keyboard and keypad input devices and pertains to systems and apparatus for analyzing physical characteristics of keystrokes for the purpose of dynamic assignment of key input function.

2. Discussion of the State of the Art

The computer keyboard has long been the most relied upon input device for computer appliances. Most keyboard input devices are serial input devices comprising a plurality of keys connected individually to circuits on a printed circuit board such that data input to a program running on the computer appliance can be achieved by typing on the keys. Some keyboards are connected to the host appliance via universal serial bus (USB). Some keyboards are built into the computer appliance and are termed keypads rather than keyboards. Laptop computers, personal digital assistants, and a host of hand-held devices employ computer keys built onto the device and arranged in a keypad.

Keyboards and keypads function in the same manner and the term keyboard will be used throughout the specification to refer to both traditional computer keyboards and onboard key entry pads that provide keystroke input for some devices. Individual keys on a keyboard may be pre-assigned different functions that may be toggled by switching modes for the keyboard. Some software applications may contain temporary assignments for certain keys of a keyboard that are in effect while the software is running on the host computer or computerized device.

Different keyboards made by different manufacturers often exhibit varying degrees of sensitivity regarding the keystroke itself. Users who operate the keys also exhibit different styles and speeds of typing. One user may be heavy handed while another may have a very light touch when typing. Therefore, some users require a more sensitive keyboard while others might do well with a less sensitive keyboard. The sensitivity of the key circuit activation is a matter of mechanics of the key relative to how it is manipulated to contact the circuit.

One problem with current-art keyboards is that a user may have to evaluate many keyboards to find one that is suitable for the style of the user. The sensitivity of the keys is a static feature and cannot be adjusted to accommodate the physical characteristics of the user. Another problem is that the keyboard, limited to the pre-assigned functions lacking flexibility that might be provided if key functions could be dynamically assigned based on the physical characteristics of a key stroke.

Therefore, what is clearly needed in the art is a system and apparatus that can dynamically assign functions to individual keys of a keyboard based on analysis of physical characteristics of a keystroke. A system such as this would provide user programmable sensitivity for keystroke function and would be more flexible in terms of functions that could be provided making users much more efficient in the process of data input.

### SUMMARY OF THE INVENTION

A problem stated above is that functions for data entry keys on a keyboard or keypad are limited to pre-assigned functions dependent on operative mode and many of the conventional means for equating functions to keystrokes are so limited. Another problem stated above is that keyboard key sensitivity is a function of the mechanics of the key and cannot be configured by a user. The inventors therefore considered functional elements of keyboard systems and software looking for elements that might be modified to provide keystroke analysis capabilities that could be leveraged to provide dynamic key assignment in a manner that would not affect efficiency.

Every keyboard or keypad has keys that may be pre-assigned or pre-configured to have two or more key functions dependant on operating mode. One by product of having only pre-assigned key functions is a lack of flexibility. Another byproduct of static sensitivity of the keys is that certain users may not be able to use certain keyboards for typing.

The present inventor realized in an inventive moment that if, at the point of manufacture, data entry keys could be provided that could be monitored according to exact movements of the keys, and the ability to provide dynamic key functionality and configurable sensitivity of keystroke might result. The inventor therefore constructed a unique data entry key and system for keyboards and keypads that allowed user sensitivity configuration and dynamic selection of key function based on analysis of keystroke characteristics. A significant improvement in efficiency of data entry results with no extra work effort required of a user.

Accordingly in one embodiment of the invention, a computer data entry key is provided comprising a key frame including at least a top plate and a bottom plate, a key motion mechanism for enabling a range of vertical movement of the key, a permanent magnet producing a magnetic field affixed to the key frame, and an electromagnet affixed to the key motion mechanism. The permanent magnetic field repels the electromagnetic field when current is introduced into the electromagnet such that upon key depression, a disturbance in the electromagnetic field occurs as a result of like polarity of the magnetic fields, the disturbance analyzed to dynamically select a specific input function for the key.

In another embodiment, a computer data entry key is provided comprising, a key frame including at least a top plate and a bottom plate, a key motion mechanism for enabling a range of vertical movement of the key, a permanent magnet producing a magnetic field affixed to the key frame, and an electromagnetic coil affixed to the key motion mechanism. In this embodiment the permanent magnetic field induces a current into the electromagnetic coil upon key depression, the current direction through the coil changes with key direction and current strength in the coil is proportional to vertical position of the key during a keystroke, the changes in current for a keystroke analyzed to dynamically select a specific input function for the key.

In one embodiment a system for analyzing keystrokes performed on a keyboard or keypad and dynamically assigning functions for each keystroke according to the results of analysis comprising, one or more electromagnetic keys each capable of output of electric current, one or more circuits for digitizing the output currents from the electromagnetic keys, at least one digital signal processor for processing the digitized signals as input and, a memory for storing key functions and a software routine for selecting and returning key functions to implement based on the results of signal processing.

According to one aspect, a method is provided for determining specific key functions for keystrokes performed on a keyboard or keypad including steps (a) providing one or more electromagnetic data entry keys each capable of output of electric current, (b) as a result of keystroke performance, disturbing the electromagnetic field of the one or more keys causing a fluctuation in the output current of the one or more keys, (c) digitizing the one or more output currents of the one or more keys subjected to one or more keystrokes, (d) on a digital signal processor, analyzing the one or more digitized signals for fluctuation results and, (e) selecting one or more specific functions for the one or more keys subjected to one or more keystrokes from a pool of available key functions based on the results of signal analysis.

In another aspect of the invention, a method is provided for determining specific key functions for keystrokes performed on a keyboard or keypad including steps (a) providing one or more data entry keys each including a permanent magnet and an electromagnetic coil having at least one current output, (b) as a result of keystroke performance, inducing a current into the magnetic coil of the one or more keys, (c) digitizing the analog output signals of the one or more keys, (d) on a digital signal processor and for each keystroke performed, analyzing the direction and strength of current through the coil associated to the key or keys subjected to the force of the keystroke and, (e) selecting one or more specific functions for the one or more keys subjected to one or more keystrokes from a pool of available key functions based on the results of signal analysis.

### BRIEF DESCRIPTION OF THE DRAWING FIGURES

FIG. 1 is an elevation view of an electromagnetic key in an elevated state according to an embodiment of the present invention.

FIG. 2 is an elevation view of the key of FIG. 1 in a depressed state.

FIG. 3 is a block diagram illustrating magnetic fields of a permanent magnet and of an electromagnet of the key of FIG. 1.

FIG. 4 is a block diagram illustrating magnetic fields of a permanent magnet and of an electromagnet of the key of FIG. 2.

FIG. 5 is a block diagram illustrating a system for analyzing signals and assigning key functions for the key of FIG. 1 according to an embodiment of the present invention.

FIG. 6 is a line graph representing several keystrokes measured by signal amplitude over time.

FIG. 7 is a process flow chart illustrating steps for dynamic assignment of a key function for the key of FIG. 1 based on signal fluctuation resulting from electromagnetic field disturbance.

FIG. 8 is a process flow chart illustrating steps for dynamic assignment of a key function for an electromagnetic key based on electromagnetic field abnormalities measured using a magnetic sensor according to another embodiment of the present invention.

### DETAILED DESCRIPTION

According to an embodiment of the present invention, the inventor provides a magnetically enhanced “smart key” system for a computer keyboard or device keypad, system capable of analyzing keystroke attributes and assigning functions based on the analysis. The methods and apparatus of the present invention are explained in enabling detail using the provided illustrations.

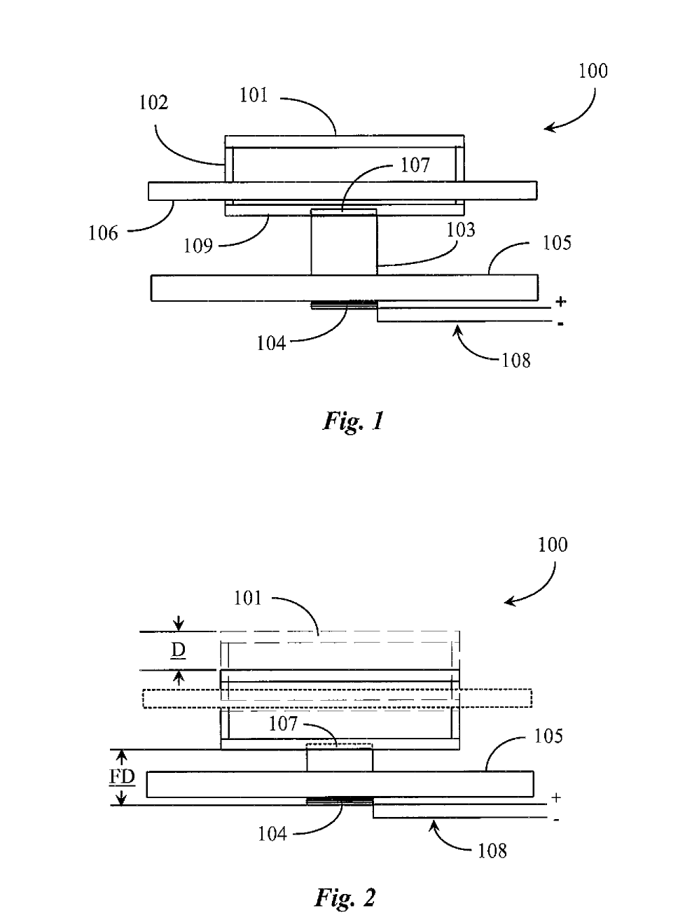

FIG. 1 is an elevation view of an electromagnetic key 100 in an elevated state according to an embodiment of the present invention. Electromagnetic key 100, also referred to herein as a “smart key” 100 is provided and may be incorporated with a plurality of same and/or similar “smart keys” on a computer keyboard or keypad comprising a system of such keys.

In one embodiment key 100 has a key frame incorporating at least a top key plate 101 and a bottom key plate 109. Plates 101 and 109 are held apart in a substantially parallel configuration to each other and in substantial true position in this example by 4 key posts 102 located strategically in the corners of the parallel key plates. Top plate 101 and bottom plate 109 are rectangular in this example but that is not required in order to practice the invention as other geometric key shapes may be incorporated to a design.

In this design there are no key walls but that is not a requirement for practicing the present invention. Key 100 may include four walls that are flexible and may be collapsed when the key is depressed. Key plates 101 and 109 maybe manufactured of a durable and transparent or semitransparent polymer in one embodiment. The key plates may be manufactured of a solid non-transparent polymer in another embodiment. In one embodiment of the invention at least top plate 101 is manufactured of a transparent translucent polymer. Transparent key plates are provided so that light sourced from below the key plate may be visible to a user operating the keyboard. Although described as one embodiment of the invention and illustrated in this example, provision of transparent or translucent keys is optional and is by no means limiting to the invention.

In this example a flexible and luminescent sheet 106 is illustrated as a source of light so that in low light conditions a user may see the key symbol of key 100 presented on the surface of top plate 101. Luminescent sheet 106 allows the key symbol to be viewed against the source of illumination and is optional and not required to practice the invention. Moreover, there are other ways to illuminate key plate 101 in the case of illuminated keys.

Smart key 100 has a key motion mechanism illustrated in this example as a vertically centered key shaft 103. Shaft 103 is a plunger provided to give the key a vertical range of depression. Key shaft or plunger 103 is manufactured of a material that is ferrous containing iron or some other magnetically permeable material in a preferred embodiment. Key shaft 103 comprises 2 hollow tubes one inserted into the other so that smart key 100 may be depressed during normal keystroke manipulation. A flexible diaphragm or a spring (not illustrated) may be provided to plunger 103 to keep key 100 elevated when not being depressed. Key 100 may be kept elevated by virtue of magnetic dynamics as discussed later in this specification.

Key 100 has a stationary key base 105 adapted to provide a bottom range of key depression. Base 105 may be manufactured of a durable polymer material and has an opening provided there through that is adapted to dimensionally accept the outer tube of key shaft 103. There are other possible key architectures and key motion mechanisms that may be provided and incorporated herein without departing from the spirit and scope of the present invention. The inventor illustrates one configuration of an open key frame and a key shaft or plunger for the purposes of discussion and as one possible and practical construction.

Key shaft 103 has an electromagnetic coil 104 wrapped around the bottom of the shaft. Shaft 103 and coil 104 extend just under key base 105 in this example. Electromagnetic coil 104 has a negative and a positive lead (leads 108) contiguously included to enable a current to course through the coil and thereby produce a uniform magnetic field around coil 104. Electromagnetic coil 104 is charged using an oscillating current in one embodiment. In another embodiment the current is a direct current enabling a consistent polarity. In still another embodiment there is no biased current introduced into coil 104. Variations of magnetic coil involvement in practice of the invention are described further below.

Bottom key plate 109 contains a permanent magnet 107 shaped like a doughnut embedded in the plate and strategically located to fit over shaft 103 when key 100 is depressed. Magnet 107 is aligned to have a polarity the same as that of electromagnet 104 such that they will repel one another with respect to magnetic fields when brought next to each other as in this example. Same polarity alignment is preferred in this example to cause the magnets to repel each other but is not absolutely required to practice the invention. Magnet 107 like electromagnet 104 produces a uniform magnetic field. The respective magnetic fields of the electromagnet and the permanent magnet do not substantially interact with each other in the elevated state for key 100 in a preferred embodiment. As described above, a diaphragm or spring may be provided to retain smart key 100 in a completely elevated state when not being manipulated. In one embodiment the repelling force of the respective magnetic fields on each other is sufficient to keep smart key 100 elevated completely.

The purpose of providing magnets in key 100 is to enable dynamic assignment of more than one key function, the assignments interpreted by electronic circuitry provided to analyze the signals output flowing through the electromagnetic coils of the keys (illustrated later in this specification). The function is selected for a key based on the fashion or characteristics of the keystroke performed on the key, namely, how a user may manipulate the key.

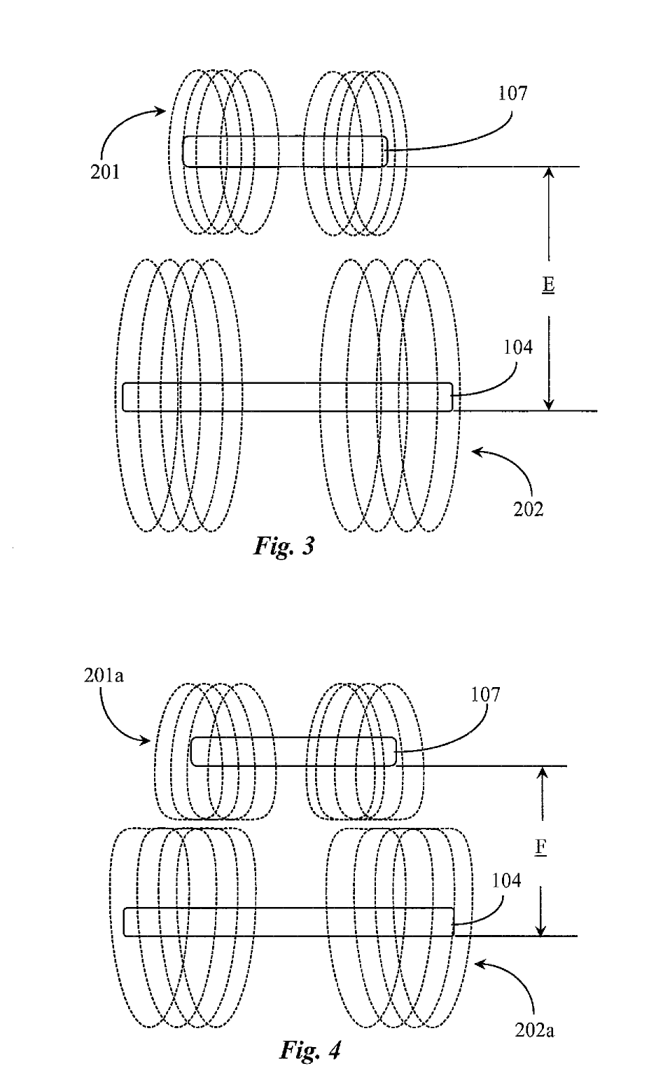

FIG. 2 is an elevation view of smart key 100 of FIG. 1 in a depressed state. Referring now to FIG. 2, smart key 100 is illustrated in a depressed state with reference to its original elevated state of FIG. 1 shown here by dotted outline. Depressing smart key 100 brings permanent magnet 107 closer to electromagnet 104 causing a deformity or disruption of the magnetic field of electromagnetic coil 104. The range or amount that key 100 is depressed in FIG. 2 is illustrated by a depression amount D. The amount that the electromagnetic field is displaced by the permanent magnet is logically illustrated herein by field displacement (FD).

In this example the force of the field of the permanent magnet working against the field of the electromagnet has a temporary resistive effect on the current flowing through electromagnetic coil 104 causing a fluctuation in the output current. Therefore in this embodiment, the temporary fluctuation is perceptible in the output (108) lead on the coil. In this example the force of depression of the key is a function of the speed the key is depressed and the range of depression of the key. In the instant the key is depressed the characteristics of the force used to depress the key are discernable through electronic monitoring of the current in the coil or output from the coil.

Every key on a keyboard or keypad might be a magnetically enhanced smart key or some of the keys may be magnetically enhanced while other keys may be typical input keys that are not magnetically enhanced. For example all of the character keys of the keyboard used for typing may be magnetically enhanced while keys used for certain static functions like “Num Lock” may not. A user may be enabled through a software interface to configure the magnetically enhanced keyboard, through the current provided in the electromagnetic coil 104, to respond to a certain range of typing force and speed. A very light and fast typist might configure the perception of force on the keys to be more sensitive while a slower and heavier typist might configure the keys to be less sensitive.

A current fluctuation defining a keystroke may be represented as a function of signal amplitude over time. The present invention may be used to determine which specific functions of a key should be returned based on a particular stroke characteristic of the key performed by a user operating the keyboard or keypad. A very heavy and short stroke may return a particular data function like returning the character of the key for typing. A light longer stroke or half stroke might cause another function to be returned like an Fn function attributed to that key. One key might have several functions available to it, each function returned according to a particular characteristic of the key stroke, which would be known by the user.

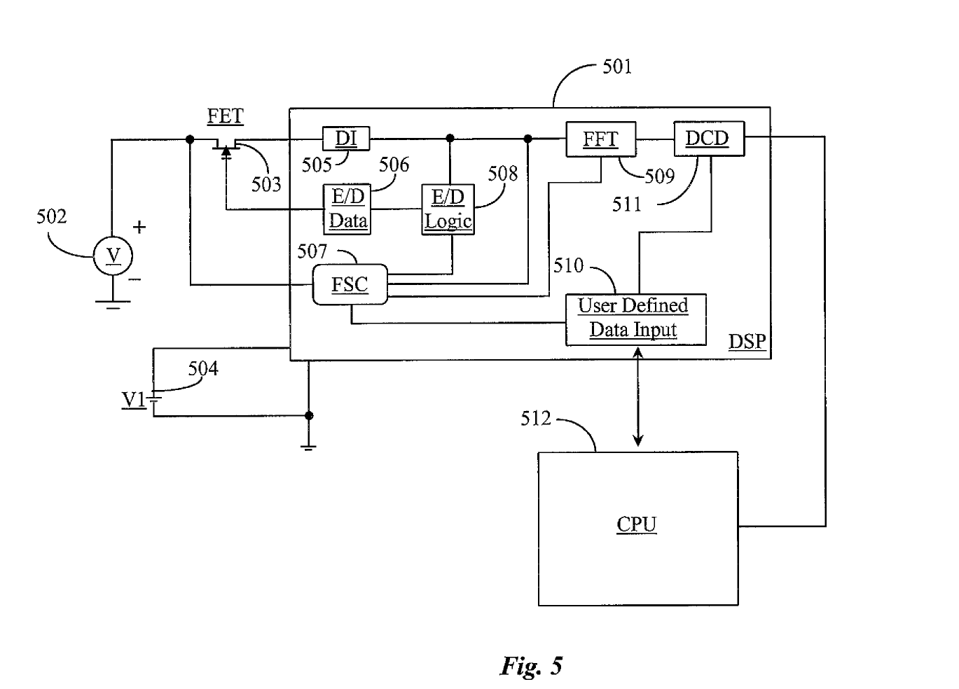

FIG. 3 is a block diagram illustrating magnetic fields of a permanent magnet and of an electromagnet of the key of FIG. 1. Referring now to FIG. 3, permanent magnet 107 has a magnetic field illustrated logically as a magnetic field 201. Permanent magnet 107 is annular and has a relatively uniform magnetic field, the field lines around the ring or doughnut shape of the magnet appearing uniform and symmetrical.

Electromagnet 104 has a magnetic field illustrated logically as a magnetic field 202. Electromagnet 104 is a coil wrapped around a shaft (103). The magnetic field (202) of electromagnet 104 is similarly uniform and symmetrical. Magnets 107 and 104 are illustrated as magnets of different size producing different size fields. This is not required to practice the invention. The magnets are only restricted in size and strength to the construction of the key and where the fields may converge. At the fully elevated state of key (100) illustrated herein as a distance E, the respective magnetic fields are not interacting with one another. In this example the fields are aligned by like magnetic poles to repel each other. The current flow through electromagnet (coil) 104 is direct bias current to retain the same polarity. An oscillating current may also be used.

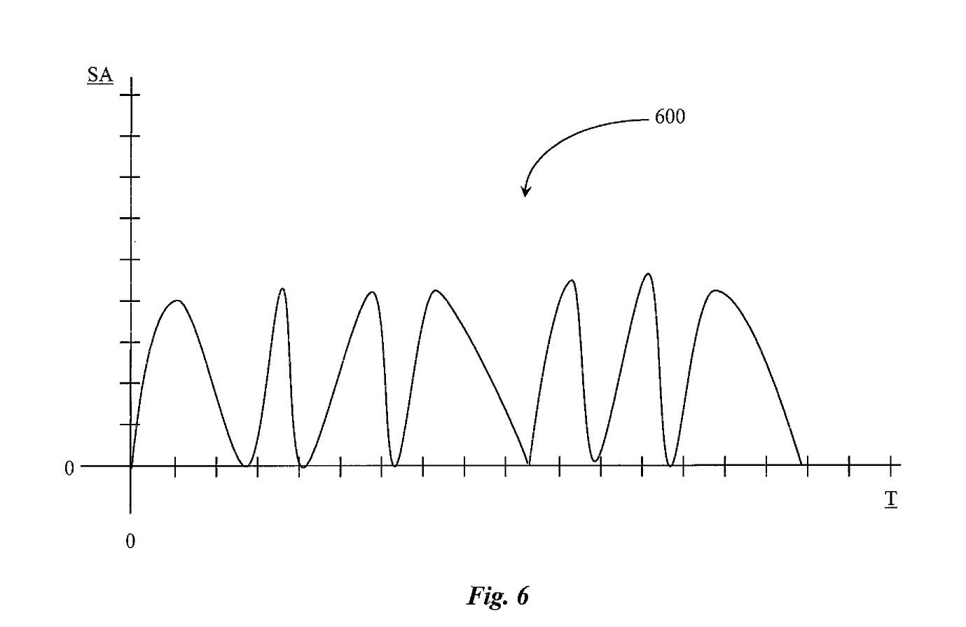

FIG. 4 is a block diagram illustrating magnetic fields of a permanent magnet and of an electromagnet of the key of FIG. 2. Referring now to FIG. 4, permanent magnet 107 is brought closer to electromagnet 104 through key depression during a keystroke as illustrated by a distance F. Permanent magnet 107 has a disturbed magnetic field 201a and electromagnet 104 has a disturbed magnetic field 202a. The illustration of the fields repelling each other is logically illustrated in this example. The actual field lines may appear much differently in actual practice. The actual disturbance is exemplified as an interruption in the magnetic flux of the electromagnet and may in one embodiment, be measured by a fluctuation in the current flow out of the coil. In a preferred embodiment only the disturbance of the electromagnetic field is relative to the present invention, although in some embodiments consideration may also be given to the disturbance of the field of the permanent magnet.

In one embodiment of the present invention no current is applied directly to the coil (104) to produce an electromagnetic field. In this embodiment the magnetic field of the permanent magnet 107 is leveraged to induce a current to flow through the coil as the magnetic field is brought near to or towards the coil by key depression. In this embodiment, the current in the coil flows in one direction when the magnet is brought closer to the coil and in the reverse direction when the magnet is brought further away from the coil to a point where there is no current in the coil (fully elevated key). The direction and strength of the induced current may be analyzed by circuitry to determine the fashion or characteristic in which the key was depressed and released. In either embodiment, variant movements of the key indicative of different characteristics of a keystroke may lead to different results in current fluctuation, strength, or speed. Those results may be equated to specific input parameters that may be used to effect different key functions or assignments. Dynamic assignment of key functions can be made by a software or firmware installed on the host device of the keyboard or keypad.

In the embodiment described above where current is induced in the coil but not directly supplied to the coil, the direction of the current indicates key direction (down or up) and the strength of the current is proportional to the speed of the key in either direction. Using this model, a variety of functions may be equated to different types of keystrokes to provide user-flexible key inputs of a same key. For example, depressing the key quickly may produce a lower case letter while depressing the key more slowly may produce an upper-case letter. This is just one of many possible examples of variant functions that may be assigned to a smart key such as key 100 based on the fashion in which the key is manipulated.

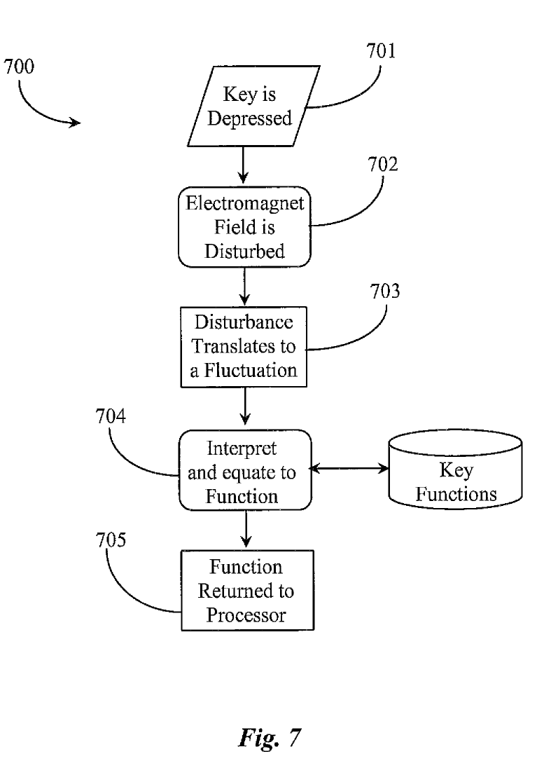

FIG. 5 is a block diagram illustrating a system for analyzing signals and assigning key functions for the smart key of FIG. 1 according to an embodiment of the present invention. Referring now to FIG. 5, electronic circuitry components are implemented to accept a signal from a smart key such as smart key 100 of FIG. 1 and to determine what function if any, an input signal may be equated to. The system ultimately assigns a function for the key based on signal analysis of the keystroke characteristics for each keystroke performed. Output from a smart key analogous to key 100 of FIG. 1 and of FIG. 2 is represented here as a voltage source 502. A digital signal processor (DSP) 501 is provided to process the signal in this example. The current passes through a field effect transistor (FET) 503 and onto DSP 501 as data input (DI) 505. A feedback signal controller (FSC) 507 is provided to enable a feedback signal to the source or key. The FET 503 is only illustrated in this example to clarify the separation between the stimulus signal from the feedback signal. In actual practice this concept will likely be integrated into the signal processor chip.

DSP 501 includes an enable/disable (E/D) data switch 506 that can be programmed to enable or to disable the user data input (DI 505) to the DSP. DSP 501 has another enable/disable feature for logic illustrated by E/D Logic switch 508. DSP 501 in this example has a power source V1 504.

A signal analysis module 509 that may be a Fast Fourier Transform (FET) module is provided to analyze the input signal. In this example results of analysis are encoded digitally to produce digitally encoded data (DCD) 511. The process relies on user defined data input 510 stored for the purpose, in this case on the DSP. A central processing unit (CPU) 512 represents the CPU of the computer to which the keyboard is attached or is otherwise in communication with. In one embodiment DSP 501 can process the signals from all “smart keys” installed on a typical computer keyboard and is part of the keyboard circuitry. In another embodiment, there may be more than one DSP on a keyboard with each individual chip handling a portion of the smart keys implemented in the keyboard.

The circuitry required to analyze the input from a smart key and to determine a correct function or assignment based on the fashion in which the key was manipulated may vary architecturally and may in part depend on the actual embodiment implemented at the key. In one embodiment, a magnetic sensor is added to the smart key implementation of FIG. 1 for measuring the change in the magnetic field of electromagnet (104) during key depression instead of the current fluctuation or in addition to current fluctuation in the coil. In another implementation of the invention, the circuitry for determining a key function from user input is based on the keyboard. Software drivers and a user interface for configuring possible preferences may be installed on the host computer. In one case only a signal analyzer is based on the keyboard and the rest of the process of determining the correct function for the key is performed by software installed on the host computer.

The circuitry implementation on the keyboard enables perception of key manipulation and analysis of the exact fashion of the key manipulation so that a user-defined preference is executed with relation to the perceived key manipulation. In one embodiment the invention applies to computer gaming wherein a user may cause certain results to be realized during play of the game according to how a user manipulates certain keys. In a computer pinball game for example, the flippers may be assigned to certain keys on the keyboard. Typically, depressing those keys produces a flipper action of a static nature regardless of how the key is manipulated. However, varying aspects of flipper action can be realized by the way the keys are depressed using the method of the present invention. Other types of functions may also be realized for other types of game actions. Functions for key assignment may be configured by a user from a set of standard functions available. In one embodiment a user may be allowed to create certain functions to customize the keyboard or keypad in a way that only the user may operate properly. Other keyboard functions might be added such as audible laughs or giggles, specific annoying sounds, screen displays, etc.

The circuitry and apparatus (electromagnetic keys) may be provided in peripheral keyboards with software drivers for installation to a computer host. Keypad devices may be manufactured with electromagnetic keys and circuitry onboard the new device. Laptops, cellular telephones, PDAs, smart phones, and other handhelds that support key-based data entry may be enhanced to practice the invention.

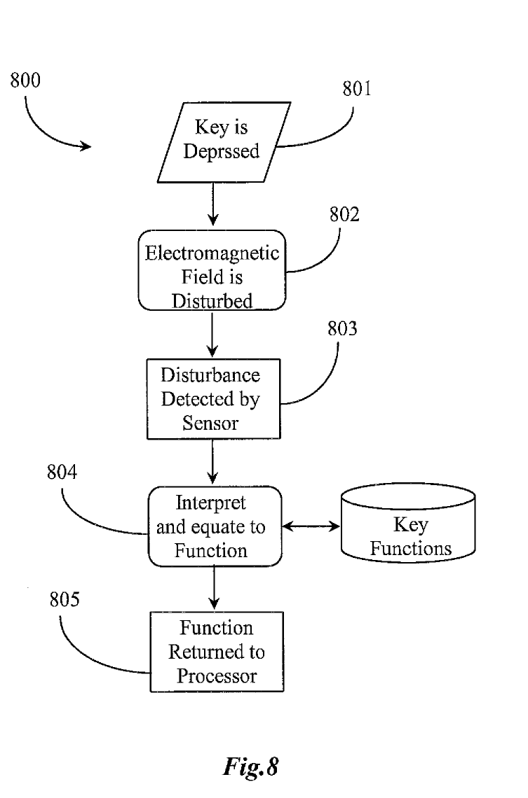

FIG. 6 is a line graph 600 representing several keystrokes measured by signal amplitude over time. Referring now to FIG. 6 line graph 600 is illustrated to show the nature of a series of key depressions (keystrokes) during key stroke analysis using a Fast Fourier Transform process. The graph illustrates an X-axis segmented for time (T) and a Y-axis segmented for signal amplitude (SA). The resulting curves of the graph illustrate varying keystrokes. In this example, the keystroke pattern has mostly consistent signal strength with some strokes defined by depressing and releasing the key occurring faster than others. In general the higher amplitude signifies a higher force of key depression in which the magnetic field of the electromagnet is maximally disturbed. Holding the key down longer produces a longer keystroke measured along the X-Axis (T). A same function such as character and number return may be ordered for a series of keystrokes made in a steady sequence where the amplitude and length of the stroke is relatively constant. A keystroke exhibiting much shorter or greater amplitude and a shorter or longer time held then the average keystroke made for typing may cause a different function to be returned for that keystroke. It is clear that actual key manipulations may be taught to a user by a manual, for example, to train the user as to how certain functions may be accessed. In one embodiment an optical sensor may provide the raw data for analysis instead of using magnetic flux or field displacement for the raw data.

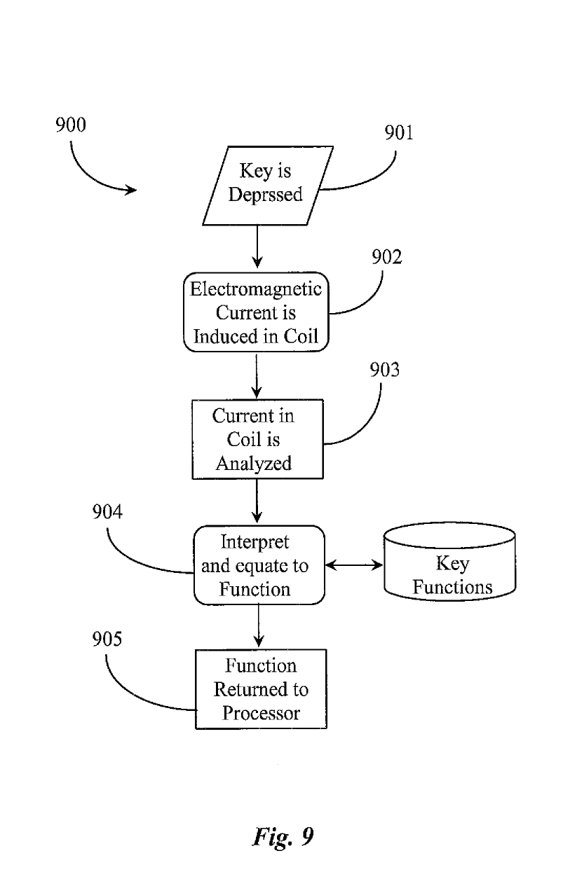

FIG. 7 is a process flow chart illustrating steps 700 for dynamic assignment of a key function for the key of FIG. 1 based on signal fluctuation resulting from electromagnetic field disturbance. Referring now to FIG. 7, a process including steps 700 begins with depression (keystroke) of a smart key in step 701. In this example the smart key is an electromagnetic key or (EMK) analogous to key 100 described above with reference to FIG. 1 and FIG. 2.

At step 702 the electromagnetic field around the coil at the base of the key motion mechanism (plunger) is disturbed as a result of bringing the pennanent magnet close to the electromagnet where the fields are polarized to repel one another. The disturbance translates to a temporary fluctuation in the current flowing through the coil in step 703. At step 703 the current fluctuation is output from the key and used as input for signal analysis.

At step 704 the fluctuation representing the keystroke is interpreted and is equated to a specific key functions for the key. The key function returned could be a user-defined key function, a preferential key function, or a generic key function. A pool of several key functions maybe available for dynamic key assignment. The specific function returned is based on the result of the analysis of the keystroke signal.

At step 705 the selected key function or preference is returned to the processor and implemented in real time. The chosen function may be a word processing function or a game function depending on the mode the user is engaged in. The function may also be a user-created function as described further above.

In this embodiment current fluctuation caused by the magnetic disturbance is measured while the magnetic circuit is supplied with a bias current to the electromagnet. In another embodiment no current is provided to the electromagnetic coil accept through induction when the permanent magnet is brought near the coil. In that case the signal may be analyzed differently as it may have different characteristics such as reversing direction depending on key direction. In this embodiment signal presence in the coil is detected and signal amplitude is measured as a function of time to determine the appropriate key function.

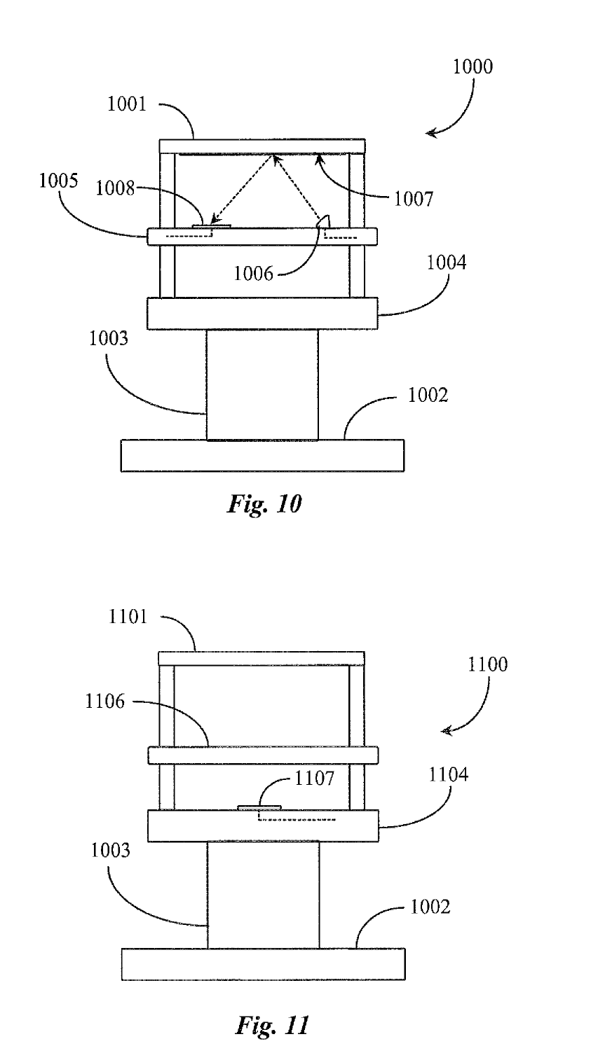

FIG. 8 is a process flow chart illustrating steps 800 for dynamic assignment of a key function for an electromagnetic key based on electromagnetic field abnormalities measured using a magnetic sensor according to another embodiment of the present invention. Referring now to FIG. 8, a process including steps 800 begins when a key is depressed in step 801. At step 802 the electromagnetic field is disturbed by a permanent magnet as described further above with respect to process step 702 of FIG. 7. At step 803 a magnetic sensor detects the magnetic disturbance of the electromagnetic field and analysis of the nature of the disturbance is performed at step 804.

In this embodiment a sensor is used instead of an FFT circuit. Therefore, the nature of analysis may be different than that described for current fluctuation. Instead of looking at signal amplitude over time there may be other criteria perceptible to a magnetic field sensor that may be defined by a signal or by encoded data.

Also in step 804 a specific key function is determined and selected based on the magnetic field analysis performed by the field sensor. In this embodiment, the magnetic field sensor is included in the construction of the key. In step 805, the function is returned to the processor for implementation analogous to step 705 of FIG. 7.

FIG. 9 is a process flow chart illustrating steps for dynamic assignment of a key function for an electromagnetic key based on analysis of current induced into an electromagnetic coil by a permanent magnet according to an embodiment of the present invention.

At step 901 the process starts when a key is depressed indicating that a keystroke is being performed. At step 902 a current is induced into the electromagnetic coil by virtue of the fact that during the depression of the key at the beginning of the keystroke, the permanent magnet is brought nearer to the coil, the current induced into the coil in one direction as the permanent magnet draws nearer. The amount of current flowing through the coil, increases to a maximum as the permanent magnet approaches. As the magnet is withdrawn from the coil at the backside of the keystroke, the current switches direction in the coil and becomes weaker until there is no current in the coil due to the distance of the permanent magnet from the coil at full key elevation.

At step 903 the characteristics of the current induction into and withdrawn from the coil are measured over time to produce a signal for processing. The signal may be a digital signal that has the amplitude curve and direction characteristics as well as the time of the event (entire keystroke).

At step 904 the signal is interpreted and equated to a specific function based on the combined characteristics of the keystroke. The signal processing may be performed on the keyboard and the function return may be performed on the host aided by software. At step 905 the correct function is returned to the processor for implementation in real time.

It will be apparent to one with skill in the art of signal processing and analysis that different versions of the circuitry may be implemented for analyzing signals produced in different ways or that include varying characteristics.

### Optical Sensing

In an alternate embodiment, electromagnetic keys are not specifically required to practice the invention. The key structure may include a light source and a light sensor that together produce analog signal data that can be used in the circuit of the invention to determine keystroke characteristics.

FIG. 10 is an elevation view of a flexible key 1000 of a keyboard according to an alternate embodiment of the invention. Key 1000 includes a durable and rigid or semi-rigid key base 1002. In this architecture a flexible support platform 1004 is attached at the top of a plunger mechanism 1003, which may be a spring-based mechanism or a resilient and flexible membrane. Support platform 1004 provides structural support for key 1000.

Key 1000 has a key top plate 1001 that may be partially translucent. The bottom surface of key top plate 1001 as a partially reflective surface coating applied to reflect light but translucent enough to allow light to pass through the key top plate. A stationary sensor platform 1005 is provided in the architecture between the key top plate and the key base plate. Sensor platform 1005 has a small light source 1006 affixed to the upper surface of the platform. Light source 1006 may be a miniature light emitting diode (LED). Light source 1006 may be powered by the host system supporting a keyboard with key 1000 being one of any number of enhanced keys. A trace is illustrated (broken line) beneath light source 1006 leading to a common power line (not illustrated) that would provide power to all enhanced keys on a keyboard.

A light sensor 1008 is provided on the upper surface of sensor platform 1005. Light sensor 1008 may be any type of light sensing device adapted to sense light emanating from light source 1006 that is reflected off of reflective surface coating 1007. In one embodiment, sensor 1008 is adapted to sense both changes in light intensity and changes in the angle of light striking the surface of the sensor. A signal trace from sensor 1008 is illustrated (broken line) leading to a common signal line that ultimately leads to a DSP module analogous to DSP processor 501 describe above with reference to FIG. 5. Fluctuations in the sensor perception of light intensity and/or angle of light indicate key motion. Frequency and intensity of the signal fluctuations represent the different characteristics of the keystroke as described in the electromagnetic key embodiment. In this embodiment changes perceived in the illumination properties surrounding the sensor are equated to user defined keystroke commands.

As reflective surface 1007 is moved closer to platform 1005, the illumination properties change accordingly. Illumination intensity is weakest at a fully elevated position relative to the key position. Illumination intensity gradually increases or decrease as the reflective surface is brought closer to the sensor. Moreover, the angle at which reflected light hits the sensor may change as the reflective surface is brought closer to the sensor. In this embodiment, light source 1006 is directed at reflective surface 1007. In one embodiment light source 1006 may be caused to switch colors. Light source 1006 may change from white light to green light, for example, as a signal (keystroke) is analyzed and processed. This may give the user some visual indication that the attempted keystroke was successfully executed. One advantage of using reflected light in this example instead of magnetism is that the light also provides a convenient illumination of the keys.

### Motion Sensing

In still another alternate embodiment motion characteristic of a keystroke is sensed using a micro-mechanical motion sensor or (MEMS) device.

FIG. 11 is an elevation view of a flexible key 1100 adapted to sense motion according to another embodiment of the invention. Key 1100 is very similar in construction to key 1000 described above. A semi-rigid key base 1002 and plunger mechanism 1003 may be interchangeable for both key types.

Key 1100 has a key top plate 1101 that may be provided totally translucent. Illumination is not required in this example so no reflective coating is necessary. Key 100 has a moveable sensor platform 1104 in this example. Unlike sensor platform 1005 described above, platform 1104 is attached to the top of plunger mechanism 1003 and moves vertically with a keystroke depression of the key. A flexible support plate 1106 is provided above sensor platform 1104 and may remain stationary during a keystroke or it may also move vertically with keystroke depression. An accelerometer 1007 is provided and attached to the upper surface of sensor platform 1104. Accelerometer 1107 is adapted to sense acceleration along a Z-axis representing vertical displacement resulting from a keystroke application.

Accelerometer 1107 may be adapted to sense gravity and acceleration and may determine an acceleration measurement by canceling gravitational influence. A signal trace is provided and illustrated (broken line) beneath sensor 1107. The signal trace may provide power to the sensor and signal output from the sensor resulting from keystroke application. In this embodiment, accelerometer 1107 may provide fluctuations in signal strength relative to the speed force and distance of key displacement that occurs with a keystroke. In this way, a user may assign different key commands to different keystroke characteristics as described in the optical and electromagnetic embodiments described further above. Key 1100 may be included with any number of such enhanced keys on a keyboard device. The signal emitted from sensor 1107 is an analog signal that is converted to a digital signal by a DSP analogous to DSP 501 described further above.

It will be apparent to one with skill in the art that the electromagnetic key system of the invention and the alternate embodiments involving optical and motion sensing may be provided using some or all of the mentioned features and components without departing from the spirit and scope of the present invention. It will also be apparent to the skilled artisan that the embodiments described above are exemplary of inventions that may have far greater scope than any of the singular descriptions. There may be many alterations made in the descriptions without departing from the spirit and scope of the present invention.

What is claimed is:

1. A computer data entry key comprising:
a key frame including at least a top plate and a bottom plate;
a key motion mechanism for enabling a range of vertical movement of the key;
a permanent magnet producing a magnetic field affixed to the key frame; and
an electromagnet affixed to the key motion mechanism;
characterized in that the permanent magnetic field repels the electromagnetic field when current is introduced into the electromagnet such that upon key depression, a disturbance in the electromagnetic field occurs as a result of like polarity of the magnetic fields, the disturbance analyzed to dynamically select a specific input function for the key.

2. A computer data entry key comprising:
a key frame including at least a top plate and a bottom plate;
a key motion mechanism for enabling a range of vertical movement of the key;
a permanent magnet producing a magnetic field affixed to the key frame; and
an electromagnetic coil affixed to the key motion mechanism;
characterized in that the permanent magnetic field induces a current into the electromagnetic coil upon key depression, the current direction through the coil changes with key direction and current strength in the coil is proportional to vertical position of the key during a keystroke, the changes in current for a keystroke analyzed to dynamically select a specific input function for the key.

3. A system for analyzing keystrokes performed on a keyboard or keypad and dynamically assigning functions for each keystroke according to the results of analysis comprising:
one or more electromagnetic keys each capable of output of electric current;
one or more circuits for digitizing the output currents from the electromagnetic keys;
at least one digital signal processor for processing the digitized signals as input; and,
a memory for storing key functions and a software routine for selecting and returning key functions to implement a function based on the results of signal processing.

4. A method for determining specific key functions for keystrokes performed on a keyboard or keypad comprising the steps:
(a) providing one or more electromagnetic data entry keys each capable of output is of electric current;
(b) as a result of keystroke performance, disturbing the electromagnetic field of the one or more keys causing a fluctuation in the output current of the one or more keys;
(c) digitizing the one or more output currents of the one or more keys subjected to one or more keystrokes;
(d) on a digital signal processor, analyzing the one or more digitized signals for fluctuation results; and
(e) selecting one or more specific functions for the one or more keys subjected to one or more keystrokes from a pool of available key functions based on the results of signal analysis.

5. A method for determining specific key functions for keystrokes performed on a keyboard or keypad comprising the steps:
(a) providing one or more data entry keys each including a permanent magnet and an electromagnetic coil having at least one current output;
(b) as a result of keystroke performance, inducing a current into the magnetic coil of the one or more keys;
(c) digitizing the output signals of the one or more keys;
(d) on a digital signal processor and for each keystroke performed, analyzing the direction and strength of current through the coil associated to the key or keys subjected to the force of the keystroke;
(e) selecting one or more specific functions for the one or more keys subjected to one or more keystrokes from a pool of available key functions based on the results of signal analysis.
